(19) United States
(12) Patent Application Publication
(10) Pub. No.: US 2005/0118336 A1
(43) Pub. Date: Jun. 2, 2005

(54) Method for the deposition of silicon nitride

(76) Inventors: Henry Bernhardt, Dresden (DE); Michael Stadtmueller, Dresden (DE); Dietmar Ottenwaelder, Fontainebleau (FR); Anja Morgenschweis, Dresden (DE)

Correspondence Address: SLATER & MATSIL LLP, 17950 PRESTON ROAD, SUITE 1000, DALLAS, TX, 75252, US

(21) Appl. No.: 10/487,952

(22) PCT Filed: Aug. 27, 2002
(86) PCT No.: PCT/DE02/03138

(30) Foreign Application Priority Data
Aug. 29, 2001 (DE) 101 42 267.9

(51) Int. Cl. C23C 16/00

(52) U.S. Cl. 427/255.394

(57) ABSTRACT

A process is described for depositing silicon nitride, in which the temperature in a furnace is set to from 600° C. to 645° C. The silicon nitride formed in this way is permeable to small molecules, such as in particular hydrogen molecules, yet nevertheless retains its etching selectivity with respect to silicon dioxide.

### BACKGROUND

1. Field

The present invention relates to a process for depositing silicon nitride on an exposed substrate.

2. Background

Silicon nitride has long been in widespread use in semiconductor technology. Two primary applications for silicon nitride in this context are for forming diffusion barriers, even to very small molecules such as hydrogen molecules, and for use as a mask in etching processes, on account of its etching selectivity with respect to silicon dioxide.

Silicon nitride usually is deposited on a substrate by the substrate being exposed, in a furnace, to a flow which substantially contains nitrogen and silicon, with simultaneous heating. It is typical to maintain temperatures of well over 700° C. in the furnace. On account of these high temperatures, the heat budget for the production or deposition of silicon nitride layers is relatively great. In this context, the term “heat budget” is to be understood as meaning the integral of the heat quantity over time. Further description in this regard is provided in U.S. Pat. No. 5,629,043.

Another problem associated with the use of silicon nitride is the high thermal budget caused by the high deposition temperature. A high thermal budget of this nature is undesirable in the development of many new types of semiconductor modules, since it can damage or destroy the results of preceding steps which already have been carried out.

For the abovementioned reasons, for some time there has been an ongoing search for new types of materials that allow the heat budget to be reduced while maintaining the other advantages associated with silicon nitride. Suitable candidates for materials of this type include RTCVD nitrides (RT=Rapid Thermal; CVD=Chemical Vapor Deposition). However, these materials are extremely expensive on account of high production and storage costs. Other materials that have been considered are based on new types of precursors, such as BTBAS (BTBAS=Bis-tertiary-butylamino-silane). Although a precursor of this nature can be used in a furnace process, like the RTCVD nitrides it is extremely expensive. Problem to be solved.

### SUMMARY

A process is disclosed for depositing silicon nitride that can be carried out in a simplified manner, and in which the silicon nitride is permeable to small molecules, such as hydrogen, without losing its etching selectivity with respect in particular to silicon nitride.

As an exemplary embodiment of the invention, a method is described for depositing silicon nitride on a silicon substrate in which the silicon substrate is exposed, in a furnace and under the action of heat. A step is provided for setting a temperature in the furnace to approximately 600° C. to 645° C. A step is also provided for providing a flow comprising a silicon component and a nitrogen component.

As further embodiments, the silicon component is selected as dichlorosilane, or the nitrogen component is selected as ammonia.

Embodiments and aspects of the invention are explained in further detail below with reference to a drawing that diagrammatically depicts a silicon nitride furnace.

### BRIEF DESCRIPTION OF THE DRAWING

FIG. 1 diagrammatically depicts a silicon nitride furnace used for performing the invention methods.

### DETAILED DESCRIPTION OF EXEMPLARY EMBODIMENTS

List of reference symbols of the drawing:
1 Silicon nitride furnace
2 Silicon wafer
3 Base
4 Heating device

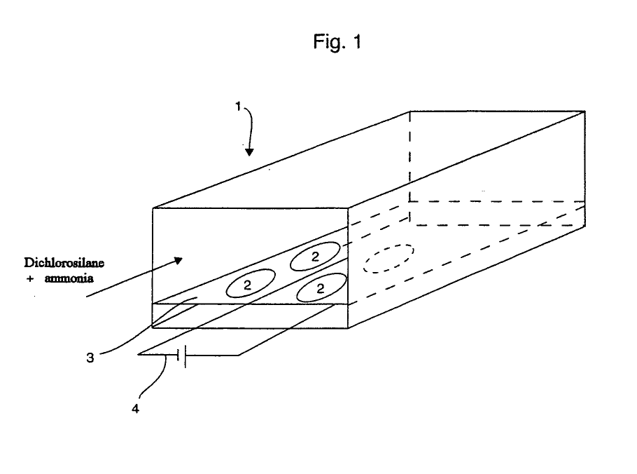

In a silicon nitride furnace 1 as illustrated in FIG. 1, silicon wafers 2 rest on a base 3, where they are heated by a heating device 4. A mixture of, for example, dichlorosilane and ammonia flows through the silicon nitride furnace 1 (cf. the arrow), so that silicon nitride is deposited on the surface of the silicon wafers 2. As an alternative to ammonia, it is also possible to use other nitrogen-containing compounds.

A significant aspect of the methods described in accordance with the present invention is that the temperature in the silicon nitride furnace 1 is not set to over 700° C., as has hitherto been customary. Rather the furnace is set to between 600° C. and 645° C., and at any rate below 650° C., in particular 620° C. The deposition of silicon nitride at these lower temperatures results in significant advantages, some of which already have been mentioned above, such as the fact that the temperature budget is reduced, and also that the silicon nitride formed at these lower temperatures has a higher hydrogen concentration, so that overall it remains permeable to hydrogen and small molecules.

Relating to a process of the type described above, this can be achieved by setting furnace temperature to 600° C. to 645° C. The temperature can be set preferably to approximately 620° C., and preferably at most 650° C. In some embodiments, the process may utilize a standard silicon furnace to produce silicon nitride. Unlike in conventional methods, however, the temperature in the furnace is not set to over 700° C., but rather to just 600° C. to 645° C., and at any rate below 650° C., and in particular to approximately 620° C. The reduced temperature means that the process consumes less heat, i.e. the heat budget is significantly lower.

Silicon nitride layers produced using the process according to exemplary embodiments of the invention have a significantly higher hydrogen concentration and also behave differently than silicon nitride produced using a conventional furnace process. Particuarly, hydrogen diffusion is not prevented, even though the etching selectivity for etching processes is retained in the same quality as with standard silicon nitride.

The properties of the silicon nitride produced by the process according to exemplary embodiments of the invention are similar to those of RTCVD nitrides, but the process can be carried out significantly more easily, and therefore at lower cost. In particular, it is possible to use any ordinary standard silicon nitride furnace, without any need for extensive conversion and therefore also without any additional investment costs being required. Rather, an significant factor is that in the process according to exemplary embodiments of the invention, the silicon nitride is deposited at temperatures between 600° C. and 645° C., and at any rate below 650° C., and preferably at approximately 620° C. T his condition alone is sufficient to ensure a higher hydrogen content in the silicon nitride and therefore also higher permeability to small molecules, such as in particular hydrogen molecules.

The foregoing disclosure of the preferred embodiments of the present invention has been presented for purposes of illustration and description. It is not intended to be exhaustive or to limit the invention to the precise forms disclosed. Many variations and modifications of the embodiments described herein will be apparent to one of ordinary skill in the art in light of the above disclosure. The scope of the invention is to be defined only by the claims appended hereto, and by their equivalents.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

The foregoing disclosure of the preferred embodiments of the present invention has been presented for purposes of illustration and description. It is not intended to be exhaustive or to limit the invention to the precise forms disclosed. Many variations and modifications of the embodiments described herein will be apparent to one of ordinary skill in the art in light of the above disclosure. The scope of the invention is to be defined only by the claims appended hereto, and by their equivalents.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

1. A method for depositing silicon nitride on a silicon substrate in which the silicon substrate is exposed, in a furnace and under the action of heat, comprising:
setting a temperature in the furnace to approximately 600° C. to 645° C.; and
providing a flow comprising a dichlorosilane silicon component and a nitrogen component.

2. The method of claim 1, wherein the temperature in the furnace is set to approximately 620° C.

3. The method of claim 1, wherein the nitrogen component is ammonia.

4. The method of claim 2, wherein the nitrogen-containing component used is ammonia.

5. The method of claim 1, whereby the silicon nitride that is formed is permeable to small molecules.

6. The method of claim 5, whereby the silicon nitride that is formed is permeable to hydrogen molecules.

7. The method of claim 1, whereby the silicon nitride that is formed retains etching selectivity with respect to silicon dioxide.

8. A method for depositing silicon nitride on a silicon substrate in which the silicon substrate is exposed, in a furnace and under the action of heat, comprising:
setting a temperature in the furnace to approximately 600° C. to 645° C.; and
providing a flow comprising a silicon component and a nitrogen component.

9. The method of claim 8, whereby the silicon nitride that is formed is permeable to small molecules.

10. The method of claim 9, whereby the silicon nitride that is formed is permeable to hydrogen molecules.

11. The method of claim 8, whereby the silicon nitride that is formed retains etching selectivity with respect to silicon dioxide.
